(19) United States
(12) Patent Application Publication
(10) Pub. No.: US 2010/0048003 A1
(43) Pub. Date: Feb. 25, 2010

(54) Plasma processing apparatus and method thereof

(75) Inventors: Doug Yong Sung, Suwon-si (KR); Vladimir Volynets, Yongin-si (KR); Andrey Ushakov, Suwon-si (KR); Min Joon Park, Yongin-si (KR); Han Soo Shin, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/382,326

(22) Filed: Mar. 13, 2009

(30) Foreign Application Priority Data
Aug. 19, 2008 (KR) 10-2008-0080673

(51) Int. Cl. H01L 21/30; C23C 16/54; C23F 1/08; H01L 21/3065

(52) U.S. Cl. 438/513; 118/723 E; 156/345.43; 438/710; 257/E21.218; 257/E21.211

(57) ABSTRACT

A plasma processing apparatus using a capacitive coupled plasma (CCP) source requiring a low pressure range of about 25 mT or less and a method thereof are disclosed. Plasma source power may be applied in a pulse mode to either one of upper and lower electrodes in a chamber, which generates plasma and processes a semiconductor substrate, and plasma maintaining power may be continuously applied to the other of the upper and lower electrodes, such that a stable pulse plasma process may be performed in a low pressure range of about 25 mT or less.

### PRIORITY STATEMENT

This application claims priority under U.S.C. §119 to Korean Patent Application No. 2008-80673, filed on Aug. 19, 2008, in the Korean Intellectual Property Office (KIPO), the entire contents of which are incorporated herein by reference.

### BACKGROUND

1. Field

Example embodiments relate to a plasma processing apparatus capable of performing a relatively stable plasma process in a relatively low pressure range of about 25 mT or less in a semiconductor manufacturing process using plasma, and a method thereof.

2. Description of the Related Art

Generally, in a semiconductor manufacturing process, a plasma processing apparatus for performing an etching (or deposition) process using plasma with respect to a semiconductor substrate may be used. The plasma processing apparatus may be largely divided into a capacitive coupled plasma (hereinafter, referred to as CCP) processing apparatus and an inductive coupled plasma (hereinafter, referred to as ICP) processing apparatus, according to a method of forming plasma.

Of the two types of apparatuses, in the CCP processing apparatus, two radio frequency (RF) power sources may be connected to upper and lower electrodes arranged in parallel in a chamber having a vacuum state, and two different RF powers (source RF power and bias RF power) may be supplied to the upper and lower electrodes so as to form an RF electric field between the electrodes. By this RF electric field, the gas within the chamber may be excited to a plasma state, and a semiconductor film formed on the lower electrode may be etched or deposited using ions and electrodes emitted from the plasma by an etching process or a deposition process, thereby processing a semiconductor substrate.

In such a CCP plasma processing apparatus, a high-frequency power of the RF power supplied to the upper and lower electrodes functions as source power to discharge and maintain the plasma, and a low-frequency power thereof functions as bias power to introduce the ions into a semiconductor wafer so as to perform the etching process.

In a RF power supply system of the CCP plasma processing apparatus using two different frequencies, when the RF power functioning as the source power is pulsed, the plasma becomes unstable in a low pressure band of about 25 mT or less, and thus, the pulse CCP having the low pressure range cannot be obtained. Accordingly, the process using the property of the pulse plasma cannot be performed in the low pressure range of about 25 mT or less, which is a particular problem when a low pulse frequency and a low duty ratio are applied in a pulse mode.

### SUMMARY

Therefore, example embodiments provide a low-pressure CCP plasma source to apply plasma source power to either one of upper and lower electrodes in a pulse mode and applying plasma maintaining power to the other of the upper and lower electrodes in a continuous mode so as to perform a stable pulse plasma process in a low pressure range of about 25 mT or less.

In accordance with example embodiments, a plasma processing apparatus may include a chamber configured to generate plasma and process a semiconductor substrate; upper and lower electrodes in the chamber; a first high-frequency power source configured to apply a first high-frequency power to either one of the upper and lower electrodes in a pulse mode; and a second high-frequency power source configured to apply a second high-frequency power to the other of the upper and lower electrodes in a continuous mode.

The plasma processing apparatus may further include a controller configured to control the first high-frequency power and the second high-frequency power. The first high-frequency power may be a plasma source power generating the plasma in a low pressure range, a duty ratio of the first high-frequency power may be about 20 to about 90%, and a pulse frequency of the first high-frequency power may be about 1 Hz to about 100 kHz. The second high-frequency power may be a plasma maintaining power maintaining the plasma in the low pressure range, and the second high-frequency power may be about 50 to about 500 W. The frequency of the first high-frequency power and the second high-frequency power may be about 40 MHz or more. The other of the upper and lower electrodes may be the electrode opposite to the electrode to which the first high-frequency power may be applied.

In accordance with example embodiments, the first high-frequency power source may be a pulse wave supplier configured to supply the high-frequency power to either one of the upper and lower electrodes in a pulse mode; and the second high-frequency power source may be a continuous wave supplier configured to supply the high-frequency power to the other of the upper and lower electrodes in a continuous mode.

The high-frequency power supplied in the pulse mode may be a plasma source power to generate the plasma in a low pressure range, a duty ratio of the plasma source power may be about 20 to about 90%, and a pulse frequency of the plasma source power may be about 1 Hz to about 100 kHz. The high-frequency power supplied in the continuous mode may be a plasma maintaining power maintaining the plasma in the low pressure range, and the plasma maintaining power may be about 50 to about 500 W.

In accordance with example embodiments, a plasma processing method may include applying a high-frequency power to upper and lower electrodes in a chamber configured to generate plasma and process a semiconductor substrate; applying the high-frequency power to either one of the upper and lower electrodes in a pulse mode; and applying the high-frequency power to the other of the upper and lower electrodes in a continuous mode so as to perform a pulse plasma process in a low pressure range.

Applying the high-frequency power to either one of the upper and lower electrodes in the pulse mode may include pulsing source power to generate the plasma and applying the source power to either one of the upper and lower electrodes. Applying the high-frequency power to the other of the upper and lower electrodes in the continuous mode may include simultaneously pulsing a source power and continuously applying the high-frequency power to maintain the plasma in the electrode opposite to the electrode to which the source power may be applied.

According to example embodiments, because the temperature of electrons in the plasma are decreased using a pulse mode in a high aspect ratio contact (HARC) process requiring a low pressure range, a dissociation degree of fluorocarbon gas may be decreased, the generation of a F radical may be suppressed, and an oxide-to-mask selection ratio may be increased. In addition, etch rate uniformity may be actively controlled using pulse parameters (pulse frequency and duty ratio), which are used as a uniformity control factor in a process apparatus having a relatively large area of about 450 mm.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIG. 1 is a block diagram showing a power supply system to perform a stable pulse plasma process in a low pressure range in a plasma processing apparatus according to example embodiments;

FIG. 2 is a conceptual diagram of FIG. 1;

FIG. 3 is a block diagram showing a power supply system to perform a stable pulse plasma process in a low pressure range in a plasma processing apparatus according to example embodiments;

FIG. 4 is a conceptual diagram of FIG. 3;

FIG. 5 is a flowchart illustrating a method of processing pulse plasma using the plasma processing apparatus of example embodiments;

FIG. 6 is a table showing the stability of the pulse plasma at about 5 mT when plasma maintaining power is not applied in a continuous mode;

FIG. 7 is a table showing the stability of the pulse plasma at about 5 mT in example embodiments in which a plasma maintaining power of about 200 W is applied in a continuous mode;

FIG. 8 is a graph showing Ar optical emission according to a processing time in a low-pressure pulse mode CCP plasma source having a pulse frequency of about 2 kHz and a duty ratio of about 50%; and

FIG. 9 is a graph showing Ar optical emission according to a processing time in a low-pressure pulse mode CCP plasma source having a pulse frequency of about 2 kHz and a duty ratio of about 75%.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described more fully hereinafter with reference to the accompanying drawings, in which example embodiments are shown. Example embodiments may, however, be embodied in different forms and should not be construed as limited to example embodiments set forth herein. Rather, example embodiments are provided so that this disclosure will be thorough and complete, and will fully convey the scope of example embodiments to those skilled in the art. In the drawings, the thickness of layers and regions are exaggerated for clarity. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

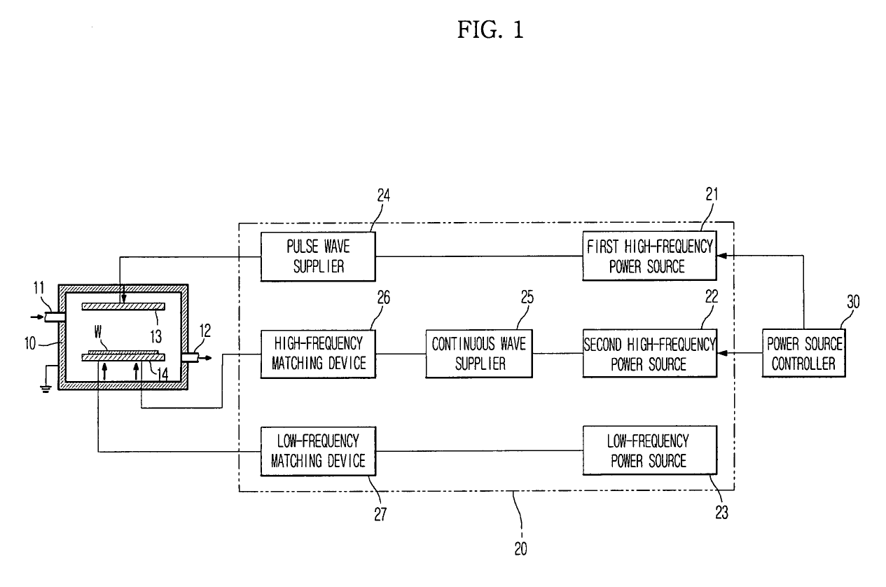

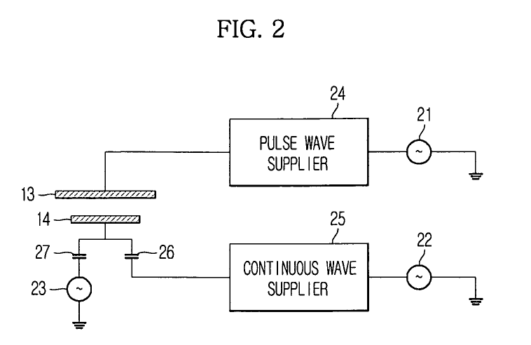

FIG. 1 is a block diagram showing a power supply system to perform a stable pulse plasma process in a low pressure range in a plasma processing apparatus according to example embodiments, and FIG. 2 is a conceptual diagram of FIG. 1. In FIGS. 1 and 2, the plasma processing apparatus according to example embodiments may include a chamber 10, a power supplier 20 and a power source controller 30.

The chamber 10 may be a vacuum chamber which performs a semiconductor manufacturing process using plasma, for example, a reactor which may have a gas inlet 11 and a gas outlet 12 and performs a process of etching a wafer W which may be a semiconductor substrate by converting gas supplied via the gas inlet 11 into a plasma state by high-frequency power and low-frequency power.

In the chamber 10, an upper electrode 13 and a lower electrode 14, to which the high-frequency power and the low-frequency power are respectively applied in order to form the plasma, may be formed so as to face each other. The upper electrode 13 may be a flat plate-shaped conductor which is disposed on the upper side of the chamber 10. High-frequency source power having a frequency of about 40 to about 100 MHz or a ground voltage may be supplied to the upper electrode 13.

The lower electrode 14 may be a flat plate-shaped conductor which is disposed on the lower side of the chamber 10 in parallel to the upper electrode 13. Low-frequency bias power having a frequency of about 2 to about 13.56 MHz may be supplied to the lower electrode 14 and an object to be processed, e.g., a wafer W, may be laid on the lower electrode 14.

The power source 20 may apply the high-frequency power or the low-frequency power to the upper and lower electrodes 13 and 14 in order to convert the gas supplied to the chamber 10 into the plasma state. The power source 20 may include a first high-frequency power source 21 to apply first high-frequency power having a frequency of about 40 to about 100 MHz, which is plasma source power, to the upper electrode 13, a second high-frequency power source 22 to apply second high-frequency power having a frequency of about 40 MHz or more to the lower electrode 14, and a low-frequency power source 23 to apply low-frequency power having a frequency of about 2 to about 13.56 MHz, which is low-frequency bias power, to the lower electrode 14.

A pulse wave supplier 24 may apply the first high-frequency power, which is the plasma source power, to the upper electrode 13 in a pulse mode in order to perform a plasma process requiring a low pressure range of about 25 mT or less, and may be connected to the first high-frequency power source 21. A continuous wave supplier 25 may apply the second high-frequency power, which is the plasma maintaining power, to the lower electrode 14 in a continuous mode in order to perform the stable pulse plasma process in the low pressure range of about 25 mT or less. A high-frequency matching device 26 may match impedance in order to deliver maximum power of the second high-frequency power to the lower electrode 14, and may be connected to the second high-frequency power source 22.

A low-frequency matching device 27, which matches impedance in order to deliver maximum power of the low-frequency power to the lower electrode 14, may be connected to the low-frequency power source 23. The pulse wave supplier 24 may pulse the first high-frequency power and may apply the pulsed first high-frequency power to the upper electrode 13 in order to perform the process using the pulse plasma property in the low pressure range of about 25 mT or less. A duty ratio may be about 20 to about 90% and a pulse frequency may be about 1 Hz to about 100 kHz.

The continuous wave supplier 25 may apply the second high-frequency power of about 50 to about 500 W to the lower electrode 14, which is the opposite electrode of the upper electrode 13, in the continuous mode in order to perform the stable pulse plasma process when the first high-frequency power applied to the upper electrode 13 is pulsed. The continuous wave supplier 25 may also restrict the value of the second high-frequency power to about 500 W or less such that the pulse plasma property may not be distorted while the plasma is stably ensured at a wide pressure range and duty ratio.

The power source controller 30 may pulse the first high-frequency power, which is the plasma source power, and may apply the second high-frequency power, which is the plasma maintaining power, in the continuous mode so as to perform the stable pulse plasma process. The power source controller 30 may control pulse parameters (pulse frequency and duty ratio) of the first high-frequency power applied to the upper electrode 13 and the value of the second high-frequency power applied to the lower electrode 14.

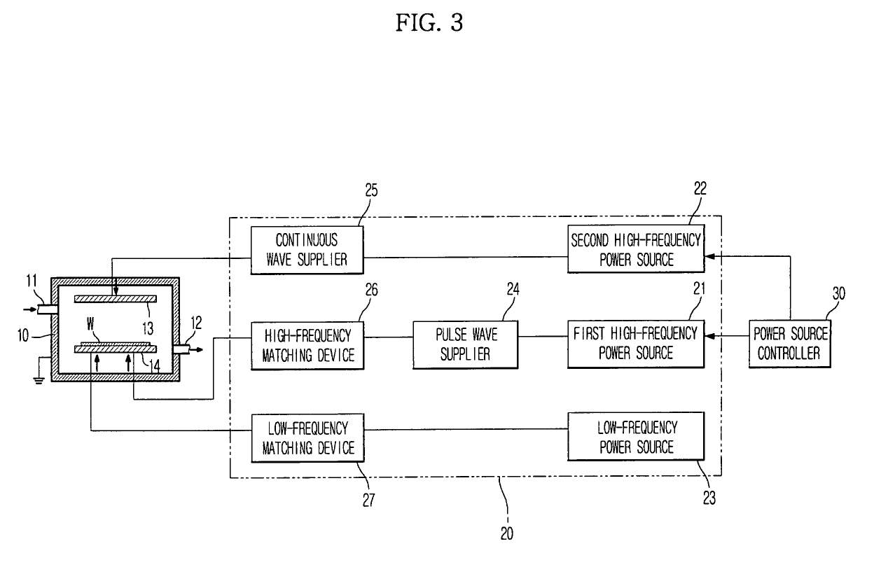

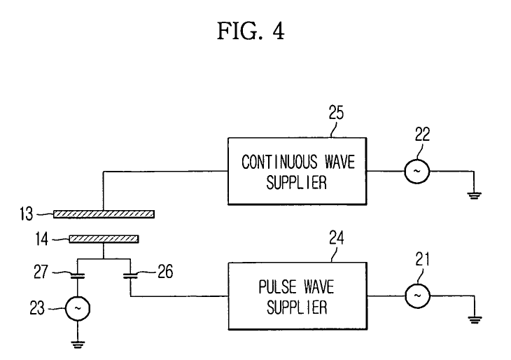

FIG. 3 is a block diagram showing a power supply system that performs a stable pulse plasma process in a low pressure range in a plasma processing apparatus according to example embodiments, and FIG. 4 is a conceptual diagram of FIG. 3. The same portions as FIGS. 1 and 2 may be denoted by the same reference numerals and thus the description thereof will be omitted. In FIGS. 3 and 4, the plasma processing apparatus according to example embodiments may include a chamber 10, a power source 20 and a power source controller 30.

In the plasma processing apparatus according to example embodiments, a first high-frequency power source 21 may apply a first high-frequency power, which is plasma source power, and may be connected to a lower electrode 14. A second high-frequency power source 22 may apply a second high-frequency power, which is plasma maintaining power, and may be connected to an upper electrode 13. The plasma source power may be applied to the lower electrode 14 in a pulse mode and the plasma maintaining power of about 50 to about 500 W may be applied to the upper electrode 13 in a continuous mode. The operations of the other components may be equal to those of the plasma processing apparatus according to the example embodiments shown in FIGS. 1 and 2. Hereinafter, the operation and the effect of the plasma processing apparatus and the method thereof will be described.

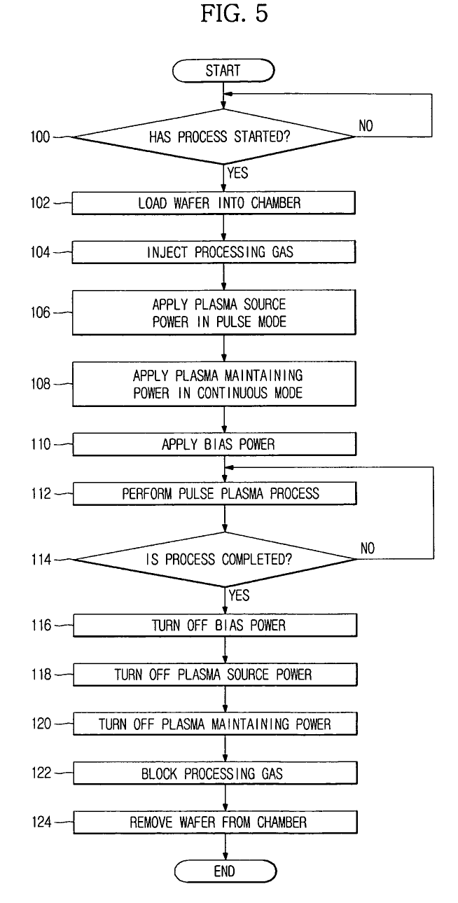

FIG. 5 is a flowchart illustrating a method of processing pulse plasma using the plasma processing apparatus of example embodiments. The method of stably performing a pulse plasma process requiring a low pressure range of about 25 mT or less will be described. In FIG. 5, if the process has started (100), a wafer W to be processed may be loaded into the chamber 10 and may be laid on the lower electrode 14 (102). Processing gas may be injected from a gas supplier (not shown) into the chamber 10 via the gas inlet 11 such that pressure may be set to the low pressure range of about 25 mT or less (104).

While the gas is injected into the chamber 11, the first high-frequency power having a frequency of about 40 to about 100 MHz, which is the plasma source power supplied from the first high-frequency power source 21, may be applied to either one of the upper and lower electrodes 13 and 14 via the pulse wave supplier 24 in the pulse mode, and the plasma for performing the process using the pulse plasma property in the low pressure range of about 25 mT or less may be generated (106).

For the pulse plasma process, the first high-frequency power applied in the pulse mode may be pulsed with a duty ratio of about 20 to about 90% and a pulse frequency of about 1 Hz to about 100 kHz and may be applied to the upper electrode 13 or the lower electrode 14. Etch rate uniformity may be actively controlled using pulse parameters (pulse frequency and duty ratio) of the first high-frequency power applied in the pulse mode.

At the same time, the second high-frequency power of about 50 to about 500 W having a frequency of about 40 MHz or more, which is the plasma maintaining power supplied from the second high-frequency power source 22, may be applied to the other of the upper electrode 13 and the lower electrode 14, for example, the electrode opposite to the electrode to which the plasma source power may be applied via the continuous wave supplier 25 in the continuous mode such that the plasma generated in the chamber 10 may be stably maintained (108).

In order to stably maintain the plasma, the plasma maintaining power applied in the continuous mode may restrict the value of the second high-frequency power to about 500 W or less such that the pulse plasma property may not be distorted. When the value of the second high-frequency power source 22 in the continuous mode is greater than about 500 W, the pulse mode property of the plasma process may be distorted such that the temperature of electrons may be increased to be close to the temperature of the continuous mode.

The low-frequency power having a frequency of about 2 to about 13.56 MHz, which is the bias power supplied from the low-frequency power source 23, may be applied to the lower electrode 14 via the low-frequency matching device 27 (110). The stable pulse plasma may be introduced into the wafer W laid on the lower electrode 14 such that an etching process or a deposition process may be performed with respect to the wafer W using ions and electrons emitted from the plasma so as to perform the stable pulse plasma process (112).

Thereafter, if the etching process of the wafer W using the pulse plasma is completed (114), the power source controller 30 may turn off the low-frequency power by applying the bias power to the lower electrode 14 (116), and may turn off the first high-frequency power, which is the plasma source power applied to either one of the upper and lower electrodes 13 and 14, and the second high-frequency power, which is the plasma maintaining power applied to the other of the upper and lower electrodes 13 and 14 (118 and 120).

At the same time, the processing gas injected into the chamber 10 via. the gas inlet 11 may be blocked (122) and the wafer W may be removed from the chamber 10 such that the pulse plasma process may be completed (124). The plasma processing apparatuses according to example embodiments may perform the plasma process of the stable pulse mode in the low pressure range of about 25 mT. Achieving stable pulsing up to about 3 mT according to the experiments of example embodiments may be possible.

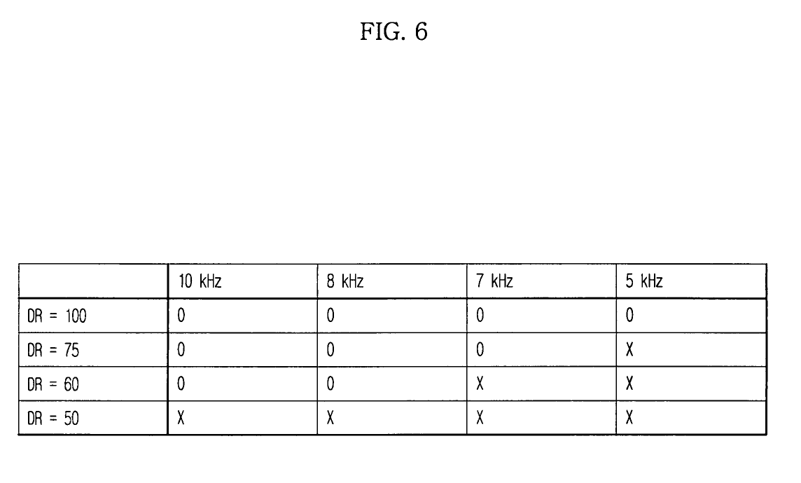

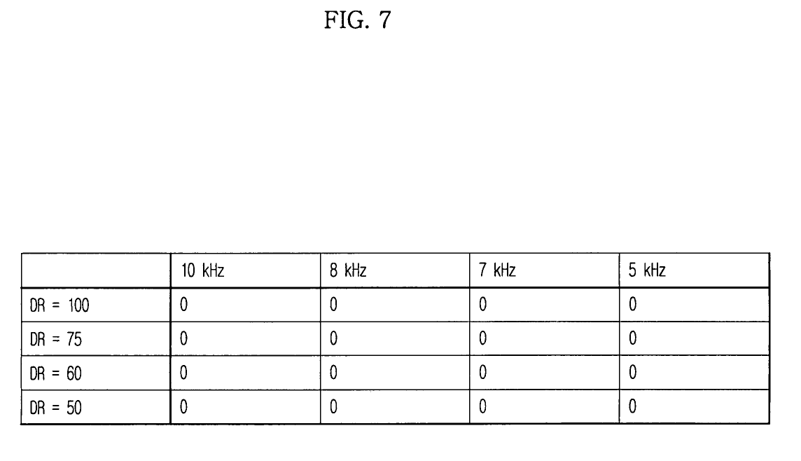

FIGS. 6 and 7 are tables for comparison of the stability of the pulse plasma depending on whether or not the plasma maintaining power may be applied. FIG. 6 is a table showing the stability of the pulse plasma at about 5 mT when the plasma maintaining power is not applied in the continuous mode, and FIG. 7 is a table showing the stability of the pulse plasma at about 5 mT when the plasma maintaining power of about 200 W is applied in the continuous mode.

In FIGS. 6 and 7, a mark ◯ represents a state in which the plasma may be stable when viewed by the naked eyes of a human being and the reflection power may be maintained to about 15 W or less. A mark × represents a state in which the plasma may be unstable (flickering) when viewed by the naked eyes of a human being and the reflection power may be equal to or greater than about 15 W or the plasma may not be maintained. As shown in FIG. 7, in example embodiments, the stability of the pulse plasma may be ensured at a very low pulse frequency (5 kHz) and a very low duty ratio (DR=50%).

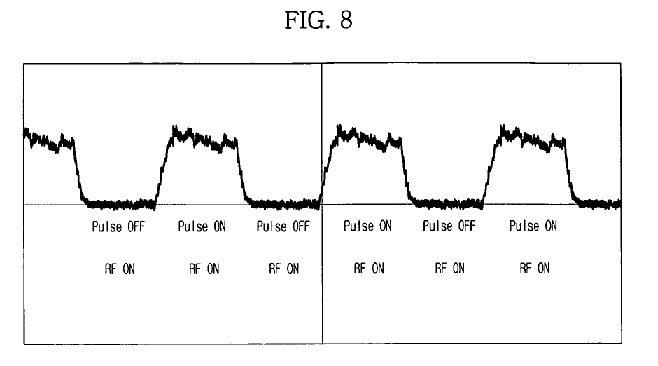

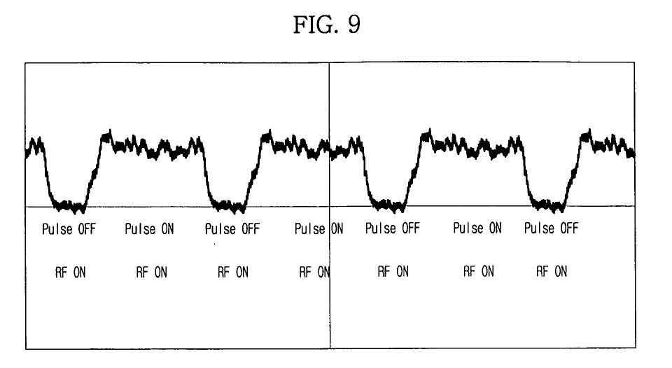

In a low-pressure pulsing condition in which the plasma maintaining power of FIG. 7 is applied, the Ar [811 nm] optical emission intensities of the processes having a pulse frequency of about 2 kHz and duty ratios of about 50 and about 75% may be plotted by a time scale and may be shown in FIGS. 8 and 9.

FIG. 8 is a graph showing Ar optical emission according to a processing time in a low-pressure pulse mode CCP plasma source having a pulse frequency of about 2 kHz and a duty ratio of about 50%, and FIG. 9 is a graph showing Ar optical emission according to a processing time in a low-pressure pulse mode CCP plasma source having a pulse frequency of about 2 kHz and a duty ratio of about 75%. As shown in FIGS. 8 and 9, the plasma may become stable and may be uniformly maintained in a pulse-on time and a pulse-off time by applying the plasma maintaining power in the continuous mode.

Although a few example embodiments have been shown and described, it would be appreciated by those skilled in the art that changes may be made in these embodiments without departing from the principles and spirit of example embodiments, the scope of which may be defined in the claims and their equivalents.

What is claimed is:

1. A plasma processing apparatus comprising:
a chamber configured to generate plasma and process a semiconductor substrate;
upper and lower electrodes in the chamber;
a first high-frequency power source configured to apply a first high-frequency power to either one of the upper and lower electrodes in a pulse mode; and
a second high-frequency power source configured to apply a second high-frequency power to the other of the upper and lower electrodes in a continuous mode.

2. The plasma processing apparatus according to claim 1, wherein the first high-frequency power is a plasma source power generating the plasma in a low pressure range.

3. The plasma processing apparatus according to claim 2, wherein a duty ratio of the first high-frequency power is about 20 to about 90%.

4. The plasma processing apparatus according to claim 2, wherein a pulse frequency of the first high-frequency power is about 1 Hz to about 100 kHz.

5. The plasma processing apparatus according to claim 2, wherein the second high-frequency power is a plasma maintaining power maintaining the plasma in the low pressure range.

6. The plasma processing apparatus according to claim 5, wherein the second high-frequency power is about 50 to about 500 W.

7. The plasma processing apparatus according to claim 5, wherein the frequency of the first high-frequency power and the second high-frequency power is about 40 MHz or more.

8. The plasma processing apparatus according to claim 1, wherein the other of the upper and lower electrodes is the electrode opposite to the electrode to which the first high-frequency power is applied.

9. The plasma processing apparatus according to claim 1, further comprising:
a controller configured to control the first high-frequency power and the second high-frequency power.

10. The plasma processing apparatus according to claim 1, wherein:
the first high-frequency power source is a pulse wave supplier configured to supply the high-frequency power to either one of the upper and lower electrodes in a pulse mode; and
the second high-frequency power source is a continuous wave supplier configured to supply the high-frequency power to the other of the upper and lower electrodes in a continuous mode.

11. The plasma processing apparatus according to claim 10, wherein the high-frequency power supplied in the pulse mode is a plasma source power generating the plasma in a low pressure range.

12. The plasma processing apparatus according to claim 11, wherein a duty ratio of the plasma source power is about 20 to about 90%.

13. The plasma processing apparatus according to claim 11, wherein a pulse frequency of the plasma source power is about 1 Hz to about 100 kHz.

14. The plasma processing apparatus according to claim 11, wherein the high-frequency power supplied in the continuous mode is a plasma maintaining power maintaining the plasma in the low pressure range.

15. The plasma processing apparatus according to claim 14, wherein the plasma maintaining power is about 50 to about 500 W.

16. The plasma processing apparatus according to claim 10, wherein the frequency of the high-frequency power is about 40 MHz or more.

17. The plasma processing apparatus according to claim 10, wherein the other of the upper and lower electrodes is the electrode opposite to the electrode to which the high-frequency power supplied in the pulse mode is applied.

18. A plasma processing method comprising:
applying high-frequency power to upper and lower electrodes in a chamber configured to generate plasma and process a semiconductor substrate;
applying the high-frequency power to either one of the upper and lower electrodes in a pulse mode; and
applying the high-frequency power to the other of the upper and lower electrodes in a continuous mode so as to perform a pulse plasma process in a low pressure range.

19. The plasma processing method according to claim 18, wherein applying the high-frequency power to either one of the upper and lower electrodes in the pulse mode comprises:
pulsing a source power to generate the plasma; and
applying the source power to either one of the upper and lower electrodes.

20. The plasma processing method according to claim 19, wherein applying the high-frequency power to the other of the upper and lower electrodes in the continuous mode comprises:
simultaneously pulsing the source power and continuously applying the high-frequency power to maintain the plasma in the electrode opposite to the electrode to which the source power is applied.

21. The plasma processing method according to claim 20, wherein a duty ratio of the source power is about 20 to about 90%.

22. The plasma processing method according to claim 20, wherein a pulse frequency of the source power is about 1 Hz to about 100 kHz.

23. The plasma processing method according to claim 20, wherein the plasma maintaining power is about 50 to about 500 W.
